(19) United States
(12) Patent Application Publication
(10) Pub. No.: US 2016/0336918 A1
(43) Pub. Date: Nov. 17, 2016

(54) ELECTROACOUSTIC FILTER AND METHOD OF MANUFACTURING AN ELECTROACOUSTIC FILTER

(71) Applicant: EPCOS AG, Munich (DE)

(72) Inventors: Ulrich KNAUER, Munich (DE); Matthias HONAL, Munich (DE); Charles BINNINGER, Antibes (FR); Thomas METZGER, Munich (DE); Masahiro NAKANO, Kawaguchi (JP); Hirohiko KAMIMURA, Amagasaki (JP); Atsushi IIJIMA, Kofu (JP)

(21) Appl. No.: 15/112,153

(22) PCT Filed: Jan. 15, 2014
(86) PCT No.: PCT/EP2014/050679

§ 371 Date: Jul. 15, 2016

(51) Int. Cl. H03H 9/64

(52) U.S. Cl. CPC H03H 9/64

(57) ABSTRACT

The present invention concerns an electroacoustic filter (1), comprising an electrode (2) having a main layer (6) which consists of a metallic material comprising an alloy of copper and molybdenum. According to a second aspect, the present invention concerns a method of manufacturing an electroacoustic filter (1), comprising the steps of: providing a substrate (3), sputtering a metallic material comprising an alloy of copper and molybdenum onto the substrate (3), annealing the metallic material, and pattering the metallic material to form a main layer (6) of an electrode (2).

The present invention concerns an electroacoustic filter and a method of manufacturing an electroacoustic filter. The electroacoustic filter may be a surface acoustic wave (SAW) filter or a bulk acoustic wave (BAW) filter. The electroacoustic filter comprises an electrode which is arranged on a piezoelectric substrate.

The electrodes of electroacoustic filters have a lot of different functions, e.g. electrical connection, electrical matching, generation and conduction of acoustic waves and interference of these waves by appropriate reflections. Thus, the materials chosen for the electrodes always require a trade-off regarding these functions. There is an additional trade-off necessary concerning chemical stability for manufacturing processes, concerning lifetime reliability and also concerning power load strength.

For example, electrodes comprising layers of pure copper are known. However, pure copper is not very stable during wet chemical processing. Furthermore, an electroacoustic filter comprising electrodes comprising pure copper layers cannot be manufactured using reactive ion etching methods which are common in other fields of microelectronics. Instead, the filter has to be manufactured in rather difficult and expensive processes.

It is an object of the present invention to provide an electroacoustic filter providing good properties regarding the above-mentioned different requirements. Further, it is another object of the present invention to provide a simple method of manufacturing an electroacoustic filter providing said good properties.

This object is solved by an electroacoustic filter according to present claim 1 and by a method of manufacturing an electroacoustic filter according to the second independent claim.

According to a first aspect of the present invention, an electroacoustic filter is provided which comprises an electrode having a main layer which consists of a metallic material comprising an alloy of copper and molybdenum. The alloy consists only of copper and molybdenum.

The main layer of the electrode may be the thickest layer of the electrode. In particular, the main layer may form at least 50 percent of the volume of the electrode. The remaining part of the electrode may be formed by other layers, e.g. by an adhesion layer, a seed layer or a cap barrier. The main layer of the electrode may be the layer which is mostly responsible for exiting an acoustic wave or for transducing an acoustic wave into an electronic signal. The main layer may be a single layer which does not have a sub-layer structure. The main layer may be the layer of the electrode which is arranged furthest away from a substrate, apart from a cap layer which may cover the entire electrode.

The alloy of copper and molybdenum provides significantly improved properties over an electrode having a main layer consisting only of copper. In particular, the power durability of the electrode is significantly enhanced. Thus, the electrode is enabled to withstand higher electrical and mechanical loads, thus resulting in an improved lifetime of the electrode. Thereby, the lifetime of the electroacoustic filter is improved. An improved lifetime corresponds to an improved reliability of the device.

When compared to alloys of copper and other elements, the alloy of copper and molybdenum provides a better conductivity. Thus, the conductivity losses which are otherwise unavoidable when a copper electrode is replaced by an electrode comprising a copper alloy can be reduced significantly.

However, the alloy shows an almost inert behaviour under wet chemical etching. The alloy shows only a minimal degree of corrosion and oxidation under wet chemical etching. Thus, other layers of the electroacoustic filter may be manufactured using said processes without damaging the main layer of the electrode, thus resulting in an easier and more precise manufacturing process.

According to one embodiment, the alloy comprises molybdenum in a total amount of 0.5 to 5.0% by weight. Preferably, the alloy comprises molybdenum in a total amount of 1.0 to 3.0% by weight. These portions of molybdenum have proven to provide the best properties regarding behaviour under chemical processing and regarding the power durability of the manufactured electrode.

In one embodiment the metallic material consists of the alloy. Thus, the metallic material does not comprise any other elements. All the above-discussed advantages can be realized best for a metallic material consisting only of the alloy.

The electroacoustic filter may be a surface acoustic wave filter or a bulk acoustic wave filter. When the electroacoustic filter is a surface acoustic wave filter, the main layer is a layer of an electrode finger arranged on a substrate. When the electroacoustic filter is a bulk acoustic wave filter, the main layer may be a layer of a flat electrode covering a significant part of a substrate.

In one embodiment, the main layer is arranged above a substrate, wherein an adhesion layer and/or a seed layer may be arranged between the main layer and the substrate. The substrate preferably comprises a piezoelectric material. In particular, the substrate may comprise LiNbO₃, LiTaO₃, Si, SiO₂ or Si in case of BAW.

The adhesion layer helps to improve the adhesion between the other layers of the electrode and the substrate. Thus, the adhesion layer may be arranged in direct contact with the substrate. The material of the adhesion layer is chosen depending on the material of the substrate and depending on the material of the other layers of the electrode. The adhesion layer may consist of one of Ti, TiN, Ru or Cr. It has been shown in experiments that an adhesion layer comprising TiN combined with a main layer consisting of the metallic material comprising an alloy of copper and molybdenum improves the power durability and thus the lifetime of the electroacoustic filter significantly.

The adhesion layer may have a thickness of up to 150 nm. In particular, the adhesion layer may have a thickness of up to 100 nm.

The seed layer may be arranged between the adhesion layer and the main layer. The seed layer may comprise one of Ag, Co, Ru, Ta, TaN, In₂O₃, Wn, TiN or HfO_{X}. The seed layers forms a diffusion barrier between the main layer and the other layers.

The seed layer may have a thickness of up to 20 nm. In particular, the seed layer may have a thickness of up to 10 nm.

Furthermore, the main layer may be covered by a cap barrier. In particular, the cap barrier may cover the entire electrode. The cap layer may comprise one of Al₂O₃, Cr₂O₃, Ta₂O₅ or TaOₓN_{y}.

Moreover, the main layer may have a thickness in the range of 40 to 500 nm. In particular, the main layer may have a thickness in the range of 80 to 400 nm.

Further, the electroacoustic filter may comprise a pad configured to connect the electrode electrically, wherein the pad may comprises a main layer comprising the metallic material. In particular, the pad may be electrically connected to electrode fingers of the electrode.

The main layer of the pad is preferably formed together with the main layer of the electrode. Thus, the main layer of the pad may have the same thickness as the main layer of the electrode and may have further structural features disclosed with respect to the main layer of the electrode. In particular, the main layer of the pad may consist of the metallic material which may consist of the alloy of copper and molybdenum.

Moreover, the pad may comprise other metal layers, e.g. an Al layer. The other metal layers of the pad may be significantly thicker than the main layer of the pad.

Another aspect of the present invention relates to a method of manufacturing an electroacoustic filter. The electroacoustic filter manufactured according to this method may correspond to the electroacoustic filter according to claim 1 or according to one of the above-discussed preferred embodiments. Thus, the electroacoustic filter manufactured by said method may comprise each structural and functional feature discussed above with respect to the electroacoustic filter.

The method comprises the steps of:

providing a substrate,

sputtering a metallic material comprising an alloy of copper and molybdenum onto the substrate,

annealing the metallic material, and

patterning the metallic material to form a main layer of the electrode.

The annealing step may be carried out at a high temperature and under a controlled gas atmosphere.

The step of patterning the metallic material may comprise a dry etching process. In particular, the dry etching process may be a reactive ion etching process.

In further manufacturing steps of the electroacoustic filter, wet chemical etching may be carried out for etching other materials than the alloy. As the metallic material shows an almost inert wet chemical behaviour, said further manufacturing steps have only a minimal impact on the main layer of the electrode. Thus, the shape and the volume of the main layer is not altered in the further manufacturing steps. Thus, the manufacturing process allows patterning the main layer very precisely. In particular, during the further steps including wet chemical etching, the main layer shows only minimal losses due to corrosion and oxidation. Thus, the metallic material according to the present invention is very well suited for this manufacturing method.

In particular, the alloy may comprise molybdenum in a total amount of 1.0 to 3.0% by weight. Moreover, the metallic material may consist of the alloy.

In the following, the present invention is described in further detail with reference to the drawings.

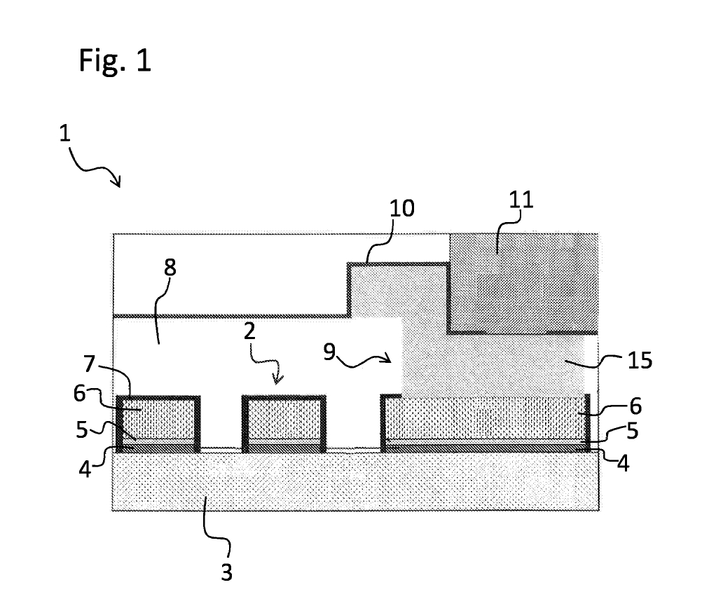

FIG. 1 shows a cross-sectional view of an electroacoustic filter.

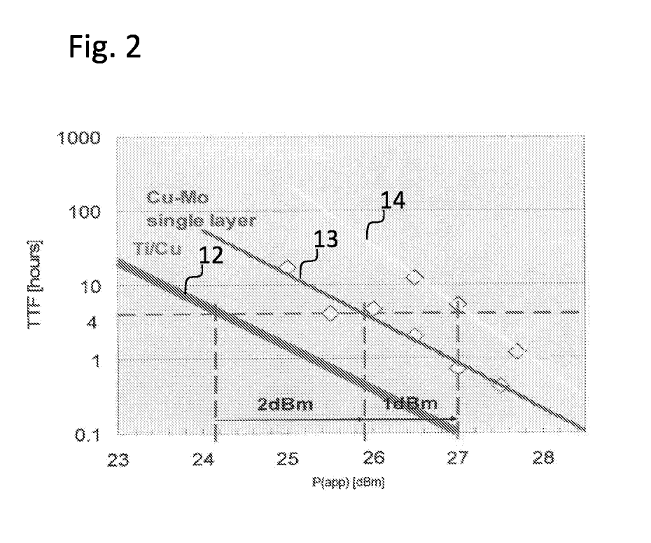

FIG. 2 shows experimental results comparing the lifetime of different electroacoustic filters.

FIG. 1 shows a cross-sectional view of an electroacoustic filter 1. In particular, the electroacoustic filter 1 is a surface acoustic wave filter. The surface acoustic wave filter comprises an electrode 2 having electrode fingers arranged on a substrate 3. The substrate 3 comprises one of the following materials LiNbO₃, LiTaO₃, Si or SiO₂. In particular, the substrate 3 may consist of one of said materials.

The electrode 2 is arranged above the substrate 3. The electrode 2 comprises a multilayer structure. The bottom layer of the electrode 2 which is in direct contact with the substrate 3 is an adhesion layer 4. The adhesion layer 4 comprises one of the following materials Ti, TiN, Ru or Cr. In particular, the adhesion layer 4 may consist of one of said materials. The adhesion layer 4 improves the adhesion of the electrode 2 on the substrate 3.

Further, the electrode 2 comprises a seed layer 5. The seed layer 5 is arranged directly above the adhesion layer 4. The seed layer 5 comprises one of Ag, Co, Ru, Ta, TaN, In₂O₃, WN, TiN or HfO_{X}. In particular, the seed layer 5 may consist of one of said materials. The seed layer 5 serves as a diffusion barrier between a main layer 6 of the electrode 2 and the adhesion layer 4.

Moreover, the electrode 2 comprises the main layer 6. The main layer 6 consists of a metallic material comprising an alloy of copper and molybdenum. The main layer 6 is arranged directly above the seed layer 5. In particular, the main layer 6 is the thickest layer of the electrode 2. In particular, the metallic material may also consist of the alloy of copper and molybdenum. The alloy comprises molybdenum in a total amount of 0.5 to 5.0% by weight, preferably in a total amount of 1.0 to 3.0% by weight.

The metallic material significantly enhances the power durability of the electroacoustic filter 1 compared to an electroacoustic filter 1 comprising a main layer of pure copper. Moreover, the metallic material further allows an improved manufacturing process as the alloy is highly wet chemical inert, as will be discussed later in more detail.

Furthermore, the electrode 2 comprises a cap barrier 7. The cap barrier 7 covers the other layers of the electrode 2. The cap barrier 7 consists of one of the following materials Al₂O₃, Cr₂O₃, Ta₂O₅ or TaOₓN_{y}.

Moreover, the electrode 2 is embedded in a protection layer 8 covering the electrode 2 and the substrate 3. The protection layer 8 comprises either pure SiO₂ or F-doped SiO₂. The protection layer 8 compensates the temperature dependency of the frequency of the electroacoustic filter 1. In particular, the compensation layer 8 may show a temperature dependent behaviour which is reciprocally proportional to the temperature dependency of the substrate 3. The protection layer 8 has a thickness in the range of 300 to 2000 nm, in particular in the range of 500 to 1500 nm.

Moreover, a pad 9 is arranged above the substrate 3. The pad 9 comprises a metal layer 15, e.g. consisting of Al, and a metallization structure arranged on the substrate 3. The metallization structure comprises the same structure as the electrode fingers. In particular, the metallization structure comprises the adhesion layer 4, the seed layer 5 and the main layer 6 comprising the metallic material. However, the adhesion layer 4 and the seed layer 5 are optional layers of the metallization structure of the pad 9.

The metal layer 15 is arranged directly above the metallization structure and is in direct contact with the metallization structure.

The electrode fingers of the electrode 2 are connected to the pad 9. Thus, the pad 9 may be used to apply an electrical signal to the electrode 2.

The metal layer 15 rises from the metallization structure in a direction away from the substrate. In its lower sub-part, the metal layer 15 has a width smaller than the width of the metallization structure, wherein the lower sub-part of the metal layer 15 is closest to the substrate 3. In an upper sub-part which is further away from the substrate 3, the metal layer 15 is shifted such that it partly overlaps with the protection layer 8.

Moreover, the complete electroacoustic filter 1 is protected by a passivation layer 10. The passivation layer 10 may be a Si₃N₄ monolayer, alternatively an Al₂O₃/Si₃N₄/Cr₂O₃ multilayer passivation or another suitable layer. The passivation layer 10 is only opened for an under bump metallization stack 11 which is connected to the pad 9. In particular, the under bump metallization stack 11 is electrically connected to the pad 9.

As already mentioned above, providing the main layer 6 comprising the metallic material consisting of the alloy of copper and molybdenum simplifies the manufacturing process. In particular, the electroacoustic filter 1 is manufactured by the following steps:

First of all, the substrate 3 is provided. In a next step, the adhesion layer 4 and the seed layer 5 can optionally be formed on the substrate 3. Moreover, in a next step, the metallic material comprising the alloy of copper and molybdenum is sputtered onto the substrate 3. Then the metallic material is annealed and after that it is patterned to form the main layer 6 of the electrode 2. In particular, the metallic material may be patterned by a dry etching process, e.g. by a reactive ion etching process.

As the metallic material has a highly wet chemical inert behaviour, the metallic material suffers only minimal losses due to corrosion and oxidation during the further manufacturing process. In particular, the further manufacturing process may be comprise a wet chemical etching step, e.g. to form the protection layer 8.

After the main layer 6 of the electrode 2 has been formed, further optional steps may be carried out. In particular, the cap barrier 7 may be applied.

Moreover, the pad 9 is formed on the substrate 9. The metallization structure of the pad 9 is formed together with the electrode 2. In particular, the pad 9 comprises the main layer 6 of the metallic material which is formed together with the main layer 6 of the electrode 2. Further, the metal layer 15 of the pad 9 is arranged above this layer. Furthermore, the electroacoustic filter 1 may be covered by the protection layer 8 and by the passivation layer 10.

FIG. 2 shows experimental results comparing the electroacoustic filter 1 according to the present invention with an electroacoustic filter having a main layer consisting of pure copper.

The power applied to the corresponding filter is plotted against the x-axis. The lifetime of the electroacoustic filter is plotted against the y-axis. A first line 12 shows the lifetime of the electroacoustic filter having a main layer consisting of copper and having an adhesion layer of Ti. The second line shows the lifetime of the electroacoustic filter 1 according to the present invention having a main layer 6 consisting of the metallic material comprising the alloy of copper and molybdenum and having an adhesion layer 4 consisting of Ti. As can be seen from FIG. 2, providing the main layer 6 of the metallic material significantly improves the lifetime of the electroacoustic filter 1.

Further, the third line 14 shows the lifetime of another electroacoustic filter 1 according to the present invention comprising a main layer 6 of the metallic material comprising the alloy of copper and molybdenum and having an adhesion layer 4 comprising TiN. As can be seen from FIG. 2, providing the adhesion layer 4 of TiN further improves the lifetime of the electroacoustic filter 1.

The described embodiment shows an SAW filter. However, the metallic material can also be used as a material of a main layer of an electrode in a BAW filter. In a BAW filter such a main layer is preferably the electrode layer that is arranged next to a piezoelectric layer of a BAW resonator. Besides this main layer one or more other metallic or other electrically conducting layers may be arranged on top of the main layer. In a BAW filter of this embodiment, the same advantages are provided, i.e. improved power durability and simplified manufacturing process due to the almost inert wet chemical behaviour.

### REFERENCE NUMERALS

1 electroacoustic filter
2 electrode
3 substrate
4 adhesion layer
5 seed layer
6 main layer
7 cap barrier
8 protection layer
9 pad
10 passivation layer
11 under bump metallization stack
12 first line
13 second line
14 third line
15 metal layer

1. An electroacoustic filter,
comprising an electrode having a main layer which consists of a metallic material comprising an alloy of copper and molybdenum.

2. The electroacoustic filter according to claim 1,
wherein the alloy comprises molybdenum in a total amount of 0.5 to 5.0% by weight.

3. The electroacoustic filter according to claim 1,
wherein the alloy comprises molybdenum in a total amount of 1.0 to 3.0% by weight.

4. The electroacoustic filter according to claim 1,
wherein the metallic material consists of the alloy.

5. The electroacoustic filter according to claim 1,
wherein the electroacoustic filter is a surface acoustic wave filter or a bulk acoustic wave filter.

6. The electroacoustic filter according to claim 1,
wherein the main layer is arranged above a substrate and wherein an adhesion layer and/or a seed layer is arranged between the main layer and the substrate.

7. The electroacoustic filter according to claim 1,
wherein the main layer is covered by a cap barrier.

8. The electroacoustic filter according to claim 1,
wherein the main layer has a thickness of 80 to 400 nm.

9. The electroacoustic filter according to claim 1,
further comprising a pad configured to connect the electrode electrically, wherein the pad comprises a main layer consisting of the metallic material comprising the alloy of copper and molybdenum.

10. Method of manufacturing an electroacoustic filter,
comprising the steps of:
providing a substrate,
sputtering a metallic material comprising an alloy of copper and molybdenum onto the substrate,
annealing the metallic material, and
patterning the metallic material to form a main layer of an electrode.

11. Method according to claim 10,
wherein the step of patterning the metallic material comprises a dry etching process.

12. Method according to claim 11,
wherein the dry etching process is a reactive ion etching process.

13. Method according to claim 10,
wherein the alloy comprises molybdenum in a total amount of 1.0 to 3.0% by weight.

14. Method according to claim 10,
wherein the metallic material consists of the alloy.

15. Method according to claim 10,
wherein, in a further manufacturing step, wet chemical etching may be carried out for etching other materials than the alloy.

16. An electroacoustic filter,
comprising an electrode having a main layer which consists of a metallic material comprising an alloy of copper and molybdenum,
wherein the alloy comprises molybdenum in a total amount of 0.5 to 5.0% by weight.
